(19) United States
(12) Patent Application Publication
(10) Pub. No.: US 2009/0315162 A1
(43) Pub. Date: Dec. 24, 2009

(54) Micro-Modules with Molded Passive Components, Systems Using the Same, and Methods of Making the Same

(76) Inventors: Yong Liu, Scarborough, ME (US); Yumin Liu, Jiangsu (CN); Terry Johnson, Cape Elizabeth, ME (US); Doug Hawks, Escondido, CA (US)

Correspondence Address: TOWNSEND AND TOWNSEND AND CREW, LLP, TWO EMBARCADERO CENTER, EIGHTH FLOOR, SAN FRANCISCO, CA, 94111-3834, US

(21) Appl. No.: 12/143,675

(22) Filed: Jun. 20, 2008

(51) Int. Cl. H01L 23/495; H01L 21/56

(52) U.S. Cl. 257/676; 438/123; 257/E23.057; 257/E21.502

(57) ABSTRACT

Semiconductor die packages, methods of making said packages, and systems using said packages are disclosed. An exemplary package comprises at least one semiconductor die disposed on one surface of a leadframe and electrically coupled to at least one conductive region of the leadframe, and at least one passive electrical component disposed on the other surface of a leadframe and electrically coupled to at least one conductive region of the leadframe. Molding material is disposed over the at least one passive electrical component to provide a molded passive component.

### CROSS-REFERENCES TO RELATED APPLICATIONS

NOT APPLICABLE

### BACKGROUND OF THE INVENTION

Personal electronic products, such as cell phones, personal data assistants, digital cameras, laptops, etc, are generally comprised of several packaged semiconductor IC chips and surface mount components assembled onto interconnect substrates, such as printed circuit boards and flex substrates. There is an ever increasing demand to incorporate more functionality and features into personal electronic products and the like. This, in turn, has placed ever increasing demands on the design, size, and assembly of the interconnect substrates. As the number of assembled components increases, substrate areas and costs increase, while demand for a smaller form factor increases.

### BRIEF SUMMARY OF THE INVENTION

As part of making their invention, the inventors have recognized that there is a need to address these issues and that it would be advantageous to find ways to enable increases in functionality and features of electronic products without causing increases in substrate areas and costs, and decreases in product yields. As also part of making their inventions, the inventors have recognized that many electronic products have several components that can be grouped together in several small groups that provide specific functions. For example, an electronic product often has one or more power conversion circuits, each of which typically comprises a control IC chip, an inductor, one or two capacitors, and sometimes a resistor or two. As another example, an electronic product may have an analog-to-digital circuit and/or a digital-to-analog circuit, each of which typically comprises an IC chip, and several resistors and capacitors. As also part of making their invention, the inventors have discovered that the substrate area required for a circuit group can be significantly decreased by incorporating the components of the circuit group into a single package.

Accordingly, a first general embodiment of the invention is directed to a semiconductor die package broadly comprising at least one semiconductor die disposed on one surface of a leadframe and electrically coupled to at least one conductive region of the leadframe, at least one location on a conductive region of the leadframe at the first surface thereof, the location being adapted to receive an electrically conductive bump, and at least one passive electrical component disposed on the other surface of a leadframe and electrically coupled to at least one conductive region of the leadframe.

Another general embodiment of the invention is directed to a method of manufacturing a semiconductor die package broadly comprising assembling at least one semiconductor die and a leadframe together at a first surface of a leadframe and with a conductive region of the die electrically coupled to at least one conductive region of the leadframe, assembling at least one passive electrical component and the leadframe together at a second surface of the leadframe and with a conductive region of the die electrically coupled to at least one conductive region of the leadframe, and assembling at least one electrically conductive bump and the leadframe together at the first surface of the leadframe and with the at least one electrically conductive bump electrically coupled to at least one conductive region of the leadframe.

Another general embodiment of the invention is directed to a method of manufacturing a semiconductor die package broadly comprising assembling at least one semiconductor die and the leadframe together at the first surface of the leadframe and with a conductive region of the die electrically coupled to at least one conductive region of the leadframe, at least one location on the conductive region at the first surface of the leadframe being left unobstructed for receiving an electrically conductive bump, assembling at least one passive electrical component and the leadframe together at a second surface of the leadframe and with a conductive region of the die electrically coupled to at least one conductive region of the leadframe, and disposing a body of electrically insulating material over the second surface of the leadframe and at least around a portion of the at least one passive electrical component.

The present invention also encompasses systems that include packages according to the present invention, each such system having an interconnect substrate and a semiconductor die package according to the present invention attached to the interconnect substrate, with electrical connections made therewith.

The invention enables the manufacture of ultra-miniature power converters and other circuits fitting within a volume on the order of 2.5 mm by 2.5 mm by 0.9 mm, and which can be used in portable consumer products, such as cell phones, MP3 players, PDAs, and the like.

The above general embodiments and other embodiments of the invention are described in the Detailed Description with reference to the Figures. In the Figures, like numerals may reference like elements and descriptions of some elements may not be repeated.

### BRIEF DESCRIPTION OF THE DRAWINGS

FIG. 1 shows a schematic diagram of a switching power supply that may be incorporated into a package according to the present invention.

FIG. 2 shows a perspective view of an exemplary semiconductor die package according to the invention.

FIGS. 3-8 show perspective views of the exemplary semiconductor die package during exemplary stages of a manufacturing process according to the invention.

FIG. 9 shows a perspective view of a semiconductor die package attached to an interconnect substrate of a system according to the present invention.

### DETAILED DESCRIPTION OF THE INVENTION

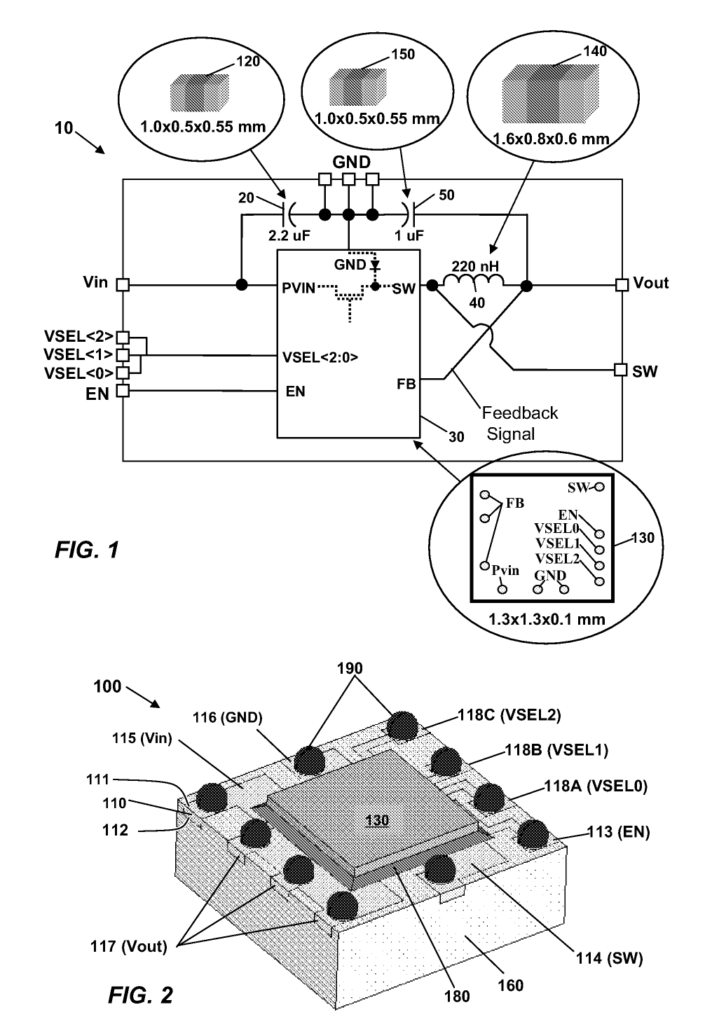

FIG. 1 shows a schematic diagram of an exemplary circuit group 10 that may be incorporated into a package according to the present invention. For illustration purposes, and without loss of generality, circuit group 10 may comprise a power conversion circuit that receives input power provided between an input voltage terminal Vin and ground terminal GND, and generates an output power supply at a different voltage level between an output terminal Vout and the ground terminal GND. Circuit group 10 includes various control inputs provided at terminals EN and VSEL<2:0>. Circuit group 10 includes an input capacitor 20 coupled between the Vin and GND terminals, a power regulator circuit 30 30 coupled between input capacitor 20 and a switch terminal SW, an inductor 40 coupled between the SW and Vout terminals, and an output capacitor 50 coupled between the Vout and GND terminals. Capacitor 20 may be implemented by a surface-mount capacitor 120, regulator circuit 30 may be implemented by a semiconductor die 130, inductor 40 may be implemented by a surface-mount inductor 140, and output capacitor 50 may be implemented by a surface-mount capacitor 160. For reference, these components are illustrated in FIG. 1. Each of components 120, 140, and 150 may have a generally box or cylindrical shape, with two conduction terminals at its distal ends.

Regulator circuit 30 has eight (8) terminals, labeled as PVIN, SW, GND, EN, FB, and VSEL<2:0>, which are coupled to the other components of circuit group 10 as shown in FIG. 1. Regulator circuit 30 switches the current in the inductor 40 by switching between the input voltage (at input capacitor 20) and ground in a repeating switching cycle. Inductor 40 is charged by the input voltage input during the first part of the cycle, and discharged to ground during the second part of the cycle. Regulator circuit 30 may comprise a power MOSFET device (shown in dashed lines) to couple inductor 40 to the input voltage during the cycle's first part, and a freewheeling rectifier (shown in dashed lines) to couple inductor 40 to ground during the cycle's second part. Regulator circuit 30 has control circuitry that monitors the output voltage provided at its input feedback terminal FB, and adjusts the timing parameters of switching cycle to regulate the output voltage Vout to a target value. Semiconductor die 130 comprises the control circuitry and the power-switching devices integrated together. While a power conversion circuit is being used to illustrate the present invention, it may be appreciated that packages of the present invention may house other types of circuit groups, and that other types of semiconductor dice and surface mount components may be used.

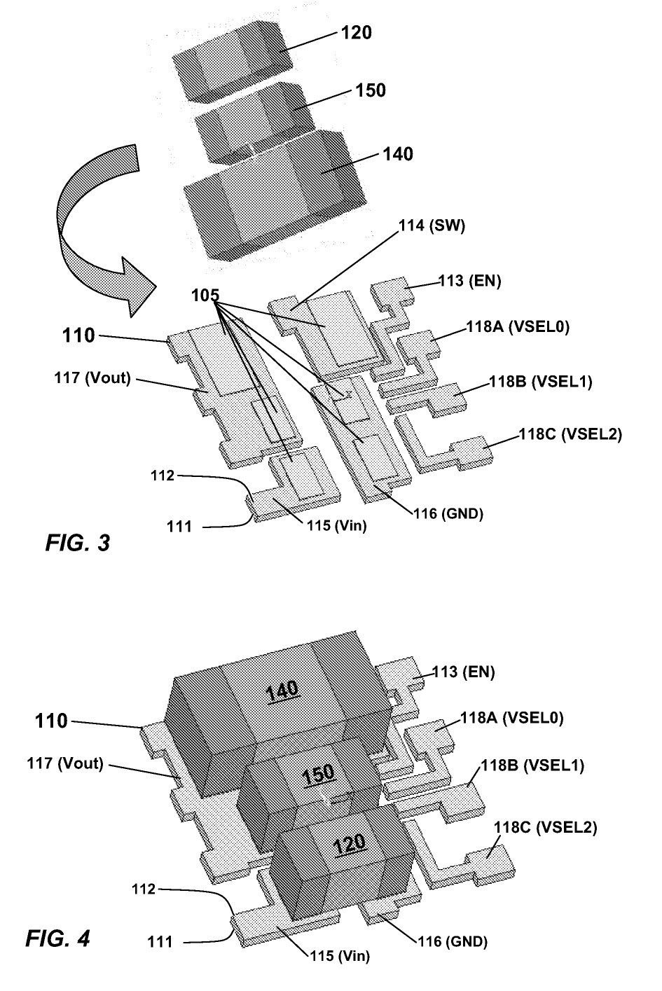

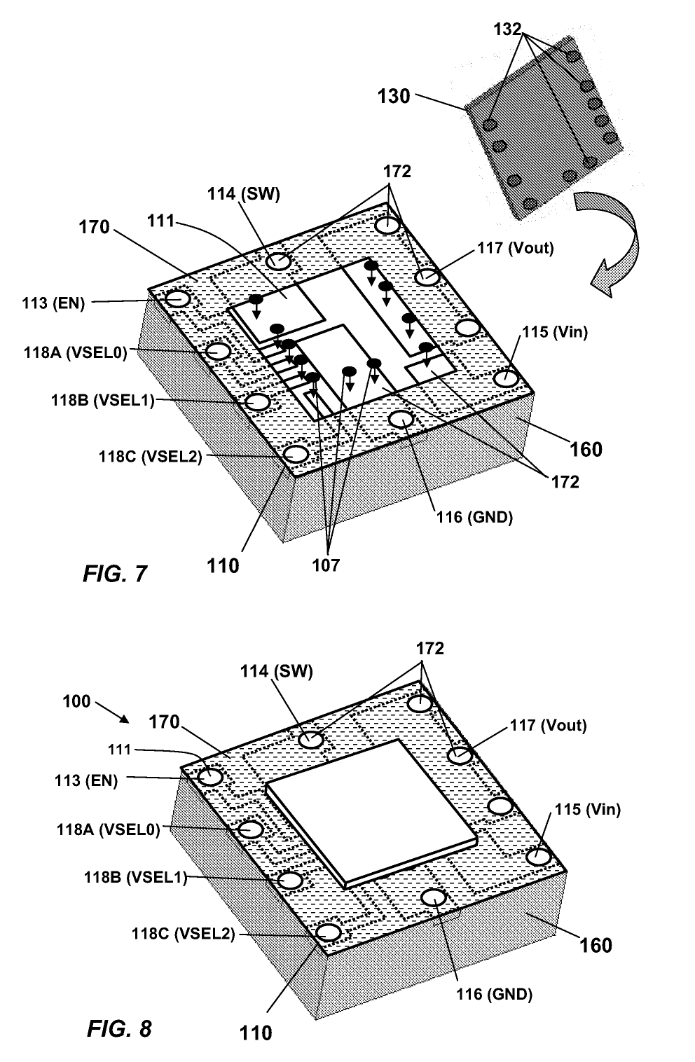

FIG. 2 shows a top perspective view of an exemplary package 100 according to the present invention. Package 100 comprises a leadframe 110 with semiconductor die 130, capacitors 120 and 150, and inductor 140 assembled thereon as shown and described below in greater detail with reference to FIGS. 3-8. Leadframe 110 has a top surface 111, a bottom surface 112, and a plurality of conductive regions 113-118C. The leadframe's top surface 111 faces the bottom of package 100, and the leadframe's bottom surface 112 faces the top of package 100. Semiconductor die 130 is assembled onto the leadframe's top surface 111. Capacitors 120, 150 and inductor 140, which are passive electrical components, are assembled onto the leadframe's bottom surface 112. An electrically insulating material 160 is disposed over the second surface of leadframe 110 and about the passive electrical components 120, 140, and 150. The top portion of inductor 140 may be left exposed by material 160 to enable the direct coupling of an electrically insulated heat sink for enhanced cooling. An underfill material 180 may be disposed between semiconductor die 130 and leadframe 110 in some implementations of package 100. Die 130 and underfill material 180 (if present) are disposed to leave the outer portions of conductive regions 113-118C around the edges of package 100 unobstructed, thereby providing electrical connection points for an external circuit. Electrically conductive bumps 190 may be disposed on the unobstructed portions of conductive regions 113-118C in some implementations of package 100. Bumps 190 may comprise solder material, electrically conductive polymeric material, a solid metal material coupled to conductive regions, etc. In addition, some implementations of package 100 may comprise a solder mask 170 (shown in FIGS. 7 and 8), to facilitate the use of some types of solder material for bumps 190, or to facilitate the placement of solder bumps for bumps 190 by customers of package 100 (in which case the package may be sold without bumps 190).

A minimum footprint of package 100 is 2.5 mm by 2.5 mm, which is 31% smaller than the typical footprint of 3 mm by 3 mm needed by an optimal discrete component implementation. A typical thickness of package 100 is about 0.9 mm, including the thickness of semiconductor die 130 (typically around 0.1 mm) but not including the height of bumps 190, and about 1 mm when the typical height of 0.2 mm for bumps 190 is included. While these thicknesses are larger than the thickness of about 0.6 mm for the discrete components, most product applications have ample vertical space and can accommodate the larger thicknesses without difficulty. With the construction of package 100 shown in FIG. 2, semiconductor die 130 and bumps 190 are each disposed on top surface 111, and the height of bumps 190 encompasses the height of semiconductor die 130. Die 130 may be left exposed, or covered by a thin protective layer having a thickness of about 0.10 mm or less, and can be thermally coupled to an external substrate, such as by thermal grease, to aid in dissipating heat.

FIGS. 3-8 illustrate an exemplary method of making package 100. Referring to FIG. 3, leadframe 110 comprises eight conductive regions 113-117 and 118A-118C disposed between its surfaces 111 and 112, each of which has a portion that will provide an external connection point to the conductive regions after insulating material 160 (shown in FIGS. 2 and 5-8) is disposed on the leadframe. Conductive regions 113-118C may be held in place by a frame that surrounds the conductive regions, which is usually made of the same material as the conductive regions, and which is later separated from the regions. Conductive region 113 receives the input enable signal EN for power supply 10, conductive region 114 provides the switch terminal SW of the power supply, conductive region 115 receives the input voltage Vin, conductive region 116 receives the ground GND, conductive region 117 provides the output voltage Vout of the power supply, and conductive regions 118A-118C receive the selection signals VSEL<2:0>. Each of the conductive regions has a portion disposed near the edge of the package footprint to provide a connection point to an external circuit, and a portion disposed near the center of the leadframe to provide a connection point to semiconductor die 130 and/or to provide a connection point to one of the passive electrical components.

Bodies 105 of electrically conductive adhesive material are disposed on conductive regions 114-117 at the leadframe's bottom surface 112, and the surface-mount components 120, 140, and 150 are placed onto appropriate ones of the conductive regions. Bodies 105 may comprise solder paste or a conductive polymeric adhesive, and may be disposed by screen printing. Components 120, 140, and 150 may be assembled by conventional surface mounting equipment and methods. Each of components 120, 140, and 150 may have a generally box or cylindrical shape, with two conduction terminals at its distal ends. Input capacitor 120 will have its conduction terminals electrically coupled to conductive regions 115 and 116, respectively, output capacitor 150 will have its conduction terminals electrically coupled to conductive regions 116 and 117, respectively, and inductor 140 will have its conduction terminals electrically coupled to conductive regions 114 and 117, respectively. Bodies 105 of conductive adhesive material may thereafter be reflowed (in the case of solder) or otherwise cured (in the case of polymeric adhesive) to complete the assembly of components 120, 140, and 150 onto leadframe 110. The resulting assembly is shown in FIG. 4. Leadframe 110 may have a thin backing sheet adhered to its top surface 111 to maintain the dimensional stability of the conductive regions during the above assembly action.

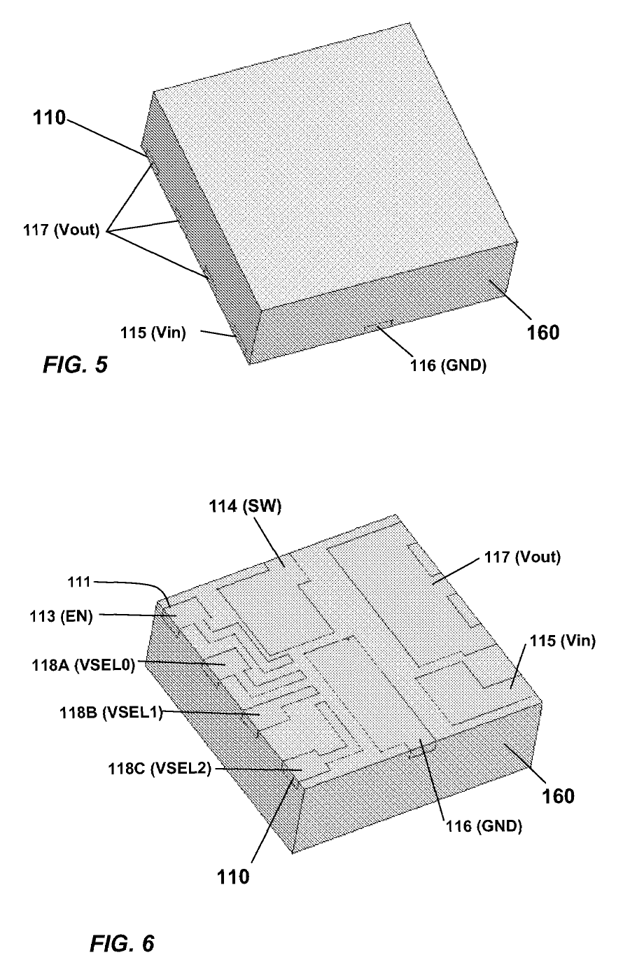

Referring to FIG. 5, electrically insulating material 160 may next be disposed over components 120, 140, and 150 and bottom surface 112 of leadframe 110. A simple molding operation may be used for this. The aforementioned thin backing sheet adhered to the top surface 111 of leadframe 110 may be used to keep the molding material from covering top surface 111 (shown in FIGS. 3-4). If the thin backing sheet is not present, other well-known techniques may be used to prevent material 160 from contacting bottom surface 112 (shown in FIGS. 3-4). Material 160 may be disposed to completely cover inductor 140. Material 160 may also be disposed to cover the sides of inductor 140 but leave the top surface exposed to allow better thermal coupling to an external heat sink. FIG. 6 is a perspective view of the package showing top surface 111 of leadframe 110. In this manner, the passive electrical components have been molded together with leadframe 110 to provide a compact, highly reliable molded component to which semiconductor die 130 may be attached.

Referring to FIG. 7, as an optional action, a solder mask 170 having a plurality of apertures 172 to define locations for solder bumps 190 may be formed on the periphery of the leadframe's top surface 111. If present, the thin backing sheet adhered to the top surface 111 of leadframe 110 is removed before forming solder mask 170. Solder mask 170 maybe formed by screen printing, a combination of deposition and etching, or other known layer formation techniques. A primary benefit of solder mask 170 is to make it easier for customers of package 100 to add their own solder bumps 190.

Still Referring to FIG. 7, semiconductor die 130 and leadframe 110 are assembled together with die 130 located in the middle of leadframe 110 and with the die's connection pads being electrically coupled to corresponding ones of the leadframe's conductive regions 113-118C. Semiconductor die 130 may be attached and electrically coupled to leadframe 110 in a number of ways, such as by gold stud flip chip bonding, flip chip bonding without the use of a solder mask, flip chip bonding with the use of a solder mask, and variations thereof. In gold stud flip chip bonding, gold stud bumps 132 are disposed on the die's electrical connection pads, the die is flipped over so that its top surface faces the inner area of the leadframe's surface 111 and so that the gold stud bumps contact corresponding conductive regions 113-118C. In one form of gold stud flip chip bonding, light pressure and ultrasonic vibrations are applied to the die to form bonds between the gold stud bumps and the conductive regions. In another form of gold stud flip chip bonding, solder paste or a polymeric conductive adhesive material (e.g., conductive epoxy) is disposed on areas of conductive regions 113-118C beforehand, such as by screen printing, the gold stud bumps are contacted with these areas, and the die and leadframe are thermally compressed together to bond the gold studs with the facing areas of conductive regions 113-118C (the heat of the thermal compression reflows the solder paste or cures the polymeric adhesive material). In flip chip bonding without the use of a solder mask, solder bumps 132 are disposed on the die's electrical connection pads, bodies 107 of solder paste are disposed on the corresponding areas of the leadframe by screen printing, the die is flipped over so that its top surface faces the inner area of the leadframe's surface 111 and so that the solder bumps contact corresponding areas of solder paste, and light pressure and heat are applied to reflow the solder paste. The solder balls may have a slightly higher melting temperature than the solder paste. Flip chip bonding with the use of a solder mask is similar, except that a solder mask is used to define to locations for the solder bumps, which aids in keeping the solder bumps from flowing out and merging with one another (solder mask 170 may be extended into the inner area of leadframe to provide the solder mask). Also, bodies of solder flux may be used instead of the bodies of solder paste. In general, gold stud flip chip bonding can provide a lower profile for die 130 (i.e., a closer positioning to the leadframe) than the solder-based flip chip bonding. As a variation, a polymer-based conductive adhesive material may be used in place of the solder, which can be dispensed in a semi-liquid or gel-like form, and thereafter cured after contacting leadframe 110.

At this point, package 100 may be separated from the frame (if present), trimmed of any flashing material, and sold to customers for use in various electrical systems. In further embodiments, an underfill material 180, shown in FIG. 2, may be disposed under semiconductor die 130 to protect the electrical connections between die 130 and package 100 from corrosion. Underfill material 180 may be disposed before, during, or after the assembly of die 130 with leadframe 110. Underfill material 180 may comprise a preformed polymer sheet with solder bumps 132 (shown in FIG. 7) formed therein, or a uniform preformed polymer sheet through which gold stud bumps or solder bumps 132 are pressed, such as when die 130 is assembled with leadframe 110 with the gold stud bumps or solder bumps being first disposed on die 130. Underfill material 180 may also comprise a material that is initially in liquid form, which is disposed around the sides of an assembled die 130 and wicked into the interior of the die's top surface by capillary action. The liquid underfill material then sets to a solid phase, which may be done by heat curing or chemical action. The back surface of semiconductor die 130 may be covered by a protective material (generally less than 0.1 mm thick), or left exposed to facilitate heat conduction to a substrate to which the finished package is to be attached. In further embodiments, electrically conductive bumps 190, shown in FIG. 2, may be assembled onto the portions of conductive regions 113-118C that are near the edge of the package's footprint. Bumps 190 may be assembled by screen printing solder paste onto the leadframe locations for the bumps, disposing the bumps on the printed locations, and reflowing the solder paste with the application of heat.

While the above manufacturing method has been illustrated with die 130 being assembled with leadframe 110 after components 120, 140, and 150 have been assembled, it may be appreciated that the method may be practiced with die 130 being assembled with leadframe 110 before components 120, 140, and 150 are assembled with leadframe 110. Also, a non-volatile solder paste (e.g., a solder paste that substantially does not emit gas upon reflow and does not require cleaning after reflow) may be used for bodies 105 and 107 of electrically conductive adhesive material. In this case, it is possible to dispose electrically insulating material 160 on leadframe 110 substantially simultaneously with the assembly of semiconductor die 130 to the leadframe, or to dispose electrically insulating material 160 on leadframe 110 substantially simultaneously with the assembly of components 120, 140, and 150 with the leadframe. As one example, semiconductor die 130 may be placed on the leadframe's top surface 111, with bodies 107 comprising non-volatile solder paste, and a mold may be placed to cover the leadframe's bottom surface 112 and the passive components 120, 140, and 150, which have been previously assembled onto the leadframe. Material 160 may then be disposed in the mold, and heat may be applied to simultaneously reflow bodies 107 and solidify/cure material 160. A plate of non-stick material, having an aperture to accept die 130, may be used to prevent material 160 from flowing over the leadframe's top surface 111. As another example, passive components 120, 140, and 150 may be placed onto leadframe 110, with bodies 105 comprising non-volatile solder paste, a mold may be placed over the components and the leadframe, material 160 may be disposed in the mold, and heat may be applied to simultaneously reflow bodies 105 and solidify/cure material 160. As another example, components 120, 140, and 150 may initially be embedded into a block of material 160 with their surfaces exposed for contact to leadframe 110, and with material 160 comprising a thermoplastic or partially cured polymeric material. The embedded components may then be placed over and aligned to leadframe 110 with heat applied from the other side of the leadframe to reflow bodies 105 of non-volatile solder paste and to cause material 160 to flow onto and adhere to leadframe 110. In this approach, it is further possible to attach die 130 at the same time (the aforementioned non-stick plate may be used), thereby enabling all of components 120-150 to be assembled with leadframe 110 simultaneously.

Accordingly, it should be understood that, where the performance of an action of any of the methods disclosed herein is not predicated on the completion of another action, the actions may be performed in any time sequence (e.g., time order) with respect to one another, including simultaneous performance and interleaved performance of various actions. (Interleaved performance may, for example, occur when parts of two or more actions are performed in a mixed fashion.) Accordingly, it may be appreciated that, while the method claims of the present application recite sets of actions, the method claims are not limited to the order of the actions listed in the claim language, but instead cover all of the above possible orderings, including simultaneous and interleaving performance of actions and other possible orderings not explicitly described above, unless otherwise specified by the claim language (such as by explicitly stating that one action proceeds or follows another action).

As noted above, package 100 provides substantial space savings over discrete component implementations. As additional advantages of the packages disclosed herein, the leadframe provides reduced series resistance among the components of the power supply, and the combination of the leadframe with insulating material 160 provides more reliable electrical connections. In addition, since the packages disclosed herein provide complete functioning circuits, the packages may be tested before being assembled onto product substrates, thereby increasing yields of the product substrates. In addition, as to power supply implementations of the packages of the present invention, the configuration of the power supply components in the packages can provide conversion efficiencies of 85% or more.

While exemplary packages 100 have been illustrated with the use of one semiconductor die, it may be appreciated that further embodiments may include two or more semiconductor die, which may be assembled onto either of the leadframe surfaces 111 or 112. In addition, while the above packages have been illustrated with the passive components (120, 140, and 150) being assembled onto the leadframe's bottom surface 112, further embodiments may include passive components mounted on the leadframe's top surface 111, such as ultra-thin surface mount resistors.

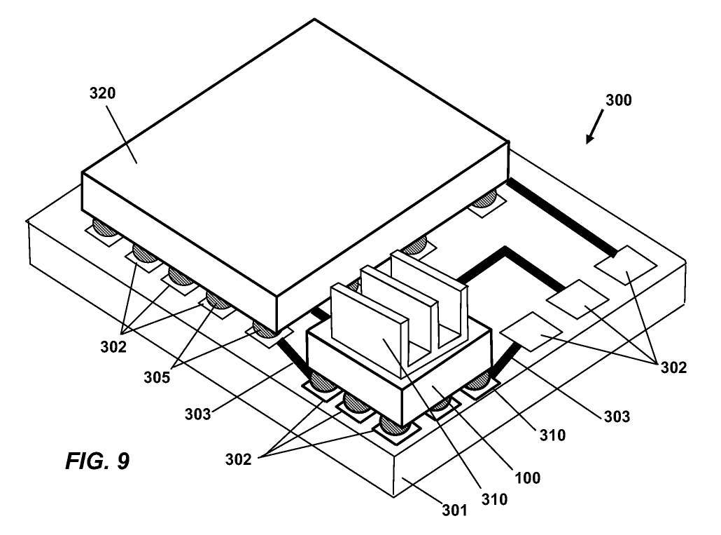

FIG. 9 shows a perspective view of a system 300 that comprises semiconductor package 100 according to the present invention. System 300 comprises an interconnect substrate 301, a plurality of interconnect pads 302 to which components are attached, a plurality of interconnect traces 303 (only a few of which are shown for the sake of visual clarity), an instance of a package according to the invention, a second package 320, and a plurality of solder bumps 305 that interconnect the packages to the interconnect pads 302. A miniature, electrically insulated heat sink 310 may be attached to package 100.

The semiconductor die packages described above can be used in electrical assemblies including circuit boards with the packages mounted thereon. They may also be used in systems such as phones, computers, etc.

Some of the examples described above are directed to “leadless” type packages such as MLP-type packages (microleadframe packages) where the terminal ends of the leads do not extend past the lateral edges of the molding material. Embodiments of the invention may also include leaded packages where the leads extend past the lateral surfaces of the molding material.

Any recitation of “a”, “an”, and “the” is intended to mean one or more unless specifically indicated to the contrary.

The terms and expressions which have been employed herein are used as terms of description and not of limitation, and there is no intention in the use of such terms and expressions of excluding equivalents of the features shown and described, it being recognized that various modifications are possible within the scope of the invention claimed.

Moreover, one or more features of one or more embodiments of the invention may be combined with one or more features of other embodiments of the invention without departing from the scope of the invention.

While the present invention has been particularly described with respect to the illustrated embodiments, it will be appreciated that various alterations, modifications, adaptations, and equivalent arrangements may be made based on the present disclosure, and are intended to be within the scope of the invention and the appended claims.

What is claimed is:

1. A semiconductor die package comprising:
a leadframe having a first surface, a second surface, and a plurality of conductive regions disposed between the first and second surfaces;
at least one semiconductor die disposed on the first surface of the leadframe and electrically coupled to at least one conductive region of the leadframe;
at least one location on a conductive region of the leadframe at the first surface thereof, the location being adapted to receive an electrically conductive bump; and
at least one passive electrical component disposed on the second surface of the leadframe and electrically coupled to at least one conductive region of the leadframe.

2. The semiconductor die package of claim 1, wherein the at least one semiconductor die has a first conductive region electrically coupled to a first conductive region of the leadframe, and wherein the at least one passive component has a first conductive region electrically coupled to the first conductive region of the leadframe.

3. The semiconductor die package of claim 1, wherein the at least one passive electrical component comprises an inductor.

4. The semiconductor die package of claim 3, further comprising a body of electrically insulating material disposed over the second surface of the leadframe and at least around a portion of the inductor.

5. The semiconductor die package of claim 3, wherein the inductor has a second conductive region electrically coupled to a second conductive region of the leadframe, and wherein the semiconductor die package further comprises a capacitor disposed on the second surface of the leadframe, the capacitor having a first electrically conductive region electrically coupled to the second conductive region of the leadframe and a second electrically conductive region electrically coupled to a third conductive region of the leadframe.

6. The semiconductor die package of claim 5, wherein the at least one semiconductor die has a second conductive region electrically coupled to a fourth conductive region of the leadframe, wherein the semiconductor die package further comprises a second capacitor disposed on the second surface of the leadframe, the second capacitor having a first electrically conductive region electrically coupled to the fourth conductive region of the leadframe and a second electrically conductive region electrically coupled to a conductive region of the leadframe.

7. The semiconductor die package of claim 5, wherein the at least one semiconductor die, inductor, and capacitor are configured to provide a boost-converter power supply.

8. The semiconductor die package of claim 1, wherein the at least one semiconductor die has a first conductive region electrically coupled to a first conductive region of the leadframe, and wherein the at least one electrically conductive bump is electrically coupled to said first conductive region of the leadframe.

9. The semiconductor die package of claim 1, wherein the at least one passive electrical component has a first conductive region electrically coupled to a first conductive region of the leadframe, and wherein the at least one electrically conductive bump is electrically coupled to said first conductive region of the leadframe.

10. The semiconductor die package of claim 9, wherein the at least one semiconductor die has a first conductive region electrically coupled to said first conductive region of the leadframe.

11. The semiconductor die package of claim 1, further comprising a body of underfill material disposed between the at least one semiconductor die and the leadframe.

12. The semiconductor die package of claim 1, further comprising at least one electrically conductive bump disposed on the at least one location.

13. The semiconductor die package of claim 1, further comprising a solder mask disposed on the first surface of the leadframe, the solder mask having at least one aperture to define the at least one location adapted to receive the electrically conductive bump.

14. The semiconductor die package of claim 13, further comprising at least one electrically conductive bump disposed on the first surface of the leadframe at the at least one aperture of the solder mask.

15. A system comprising an interconnect substrate and the semiconductor die package of claim 1 attached to the interconnect substrate.

16. A method of manufacturing a semiconductor die package, the method comprising:
assembling at least one semiconductor die and a leadframe together at a first surface of a leadframe and with a conductive region of the die electrically coupled to at least one conductive region of the leadframe;
assembling at least one passive electrical component and the leadframe together at a second surface of the leadframe and with a conductive region of the die electrically coupled to at least one conductive region of the leadframe; and
assembling at least one electrically conductive bump and the leadframe together at the first surface of the leadframe and with the at least one electrically conductive bump electrically coupled to at least one conductive region of the leadframe.

17. The method of claim 16 wherein the at least one passive electrical component and the leadframe are assembled together before the at least one semiconductor die and the leadframe are assembled together.

18. The method of claim 16 wherein the at least one semiconductor die and the leadframe are assembled together before the at least one passive electrical component and the leadframe are assembled together.

19. The method of claim 16 further comprising disposing a body of electrically insulating material over the second surface of the leadframe and at least around a portion of the at least one passive electrical component.

20. The method of claim 16 wherein assembling the at least one semiconductor die and the leadframe together comprises gold stud flip chip bonding the die to the first surface of the leadframe.

21. The method of claim 16 wherein assembling the at least one semiconductor die and the leadframe together comprises disposing solder paste on one or more locations of the first surface of the leadframe and solder-bump flip-chip bonding the die to the first surface of the leadframe.

22. A method of manufacturing a semiconductor die package, the method comprising:
assembling at least one semiconductor die and the leadframe together at the first surface of the leadframe and with a conductive region of the die electrically coupled to at least one conductive region of the leadframe, at least one location on the conductive region at the first surface of the leadframe being left unobstructed for receiving an electrically conductive bump; and
assembling at least one passive electrical component and the leadframe together at a second surface of the leadframe and with a conductive region of the die electrically coupled to at least one conductive region of the leadframe; and
disposing a body of electrically insulating material over the second surface of the leadframe and at least around a portion of the at least one passive electrical component.

23. The method of claim 22 wherein the at least one passive electrical component and the leadframe are assembled together before the at least one semiconductor die and the leadframe are assembled together.

24. The method of claim 22 wherein the at least one semiconductor die and the leadframe are assembled together before the at least one passive electrical component and the leadframe are assembled together.

25. The method of claim 22 further comprising disposing a solder mask on a first surface of a leadframe, the solder mask having at least one aperture to define a location for an electrically conductive bump.

26. The method of claim 22 wherein assembling the at least one semiconductor die and the leadframe together comprises gold stud flip chip bonding the die to the first surface of the leadframe.

27. The method of claim 22 wherein assembling the at least one semiconductor die and the leadframe together comprises disposing solder paste on one or more locations of the first surface of the leadframe and solder-bump flip-chip bonding the die to the first surface of the leadframe.
